(19) United States
(12) Patent Application Publication
(10) Pub. No.: US 2022/0028571 A1
(43) Pub. Date: Jan. 27, 2022

(54) SEMICONDUCTOR DEVICES BEING EXPOSED TO RADIATION

(71) Applicant: AwareAbility Technologies, LLC, Columbus, OH (US)

(72) Inventor: R Gregory Downing, Columbus, OH (US)

(73) Assignee: AwareAbility Technologies, LLC, Columbus, OH (US)

(21) Appl. No.: 17/382,260

(22) Filed: Jul. 21, 2021

Related U.S. Application Data
(60) Provisional application No. 63/056,071, filed on Jul. 24, 2020.

(51) Int. Cl. G21H 1/02; H01L 31/102; H01L 31/16; H01L 31/0224

(52) U.S. Cl. CPC G21H 1/02; H01L 31/102; G21H 1/06; H01L 31/022408; H01L 31/165

(57) ABSTRACT

Disclosed herein is a device that includes at least one functional semiconductor element; and static electric field source(s) associated with the at least one functional semiconductor element, the static electric field source(s) comprising at least one electret component and having a heterogeneous charge distribution. Also disclosed herein is a device includes a functional semiconductor element; a static electric field source comprising at least one electret element, the static electric field source imparting a static electric field to the functional semiconductor element; and at least one nuclear radiation source for continuously imparting nuclear beta radiation to the at least one electret element and/or the functional semiconductor element. Use of at least a radioactive beta source for replenishing charge in an electret, as well as use of at least a radioactive beta source for simultaneously replenishing charge in an electret and modifying charge mobility of a semiconductor material, are also disclosed. A nuclear battery includes at least one functional semiconductor element; at least one radiation source imparting nuclear radiation to the at least one functional semiconductor element; and at least one electret imparting a static electric field to the at least one functional semiconductor element.

### CROSS-REFERENCE TO RELATED APPLICATION

This application claims priority under 35 U.S.C. § 120 to U.S. Provisional Patent Application No. 63/056,071 filed on Jul. 24, 2020, the contents of which are incorporated herein by reference.

### FIELD OF THE INVENTION

The following relates generally to semiconductor devices, and more particularly to enhancing the effectiveness of semiconductor devices being exposed to radiation.

### BACKGROUND OF THE INVENTION

Semiconductor devices of various types are deployed ubiquitously in electronics applications. Applications requiring detection of incident radiation and/or harvesting of energy from radiation can incorporate semiconductor devices. For example, various self-powered radiation detectors, nuclear batteries, and photoelectric devices incorporate semiconductor devices. In applications such as these, incidental or deliberately applied radiation reaching the semiconductor material forms numbers of electron-hole pairs in proportion to the intensity of the radiation. These electron-hole pairs propagate through the volume of semiconductor material until reaching electrodes, resulting in electrical current through the electrodes that can be electrically conveyed downstream. Downstream circuitry may serve to register the existence or amount of incident radiation based on the amount of electrical current conveyed and/or may serve to condition the electrical current more generally as a supply of electrical power for storage or immediate work.

Various types of semiconductor devices are available for use in applications involving radiation detection and/or power generation. For example, a semiconductor diode—a semiconductor device permitting electrical current to pass in only one direction through the device—can be used for such applications.

Various types of semiconductor diodes are available. For example, a PN junction diode is formed by fusing an N-type semiconductor to a P-type semiconductor, thereby creating a potential barrier voltage across the interface, resulting in a charge depletion region. When such a diode is connected in a zero-bias configuration, no external potential energy is applied to the PN junction. When terminals of the diode are shorted together, a few holes (majority carriers) in the P-type material with enough energy to overcome the potential barrier voltage will move across the junction against this barrier potential voltage.

A Schottky diode has an advantage over the conventional silicon PN junction diode in that it features a substantially lower forward voltage drop. This is achieved by bonding just a metal electrode to an N-type semiconductor, rather than sandwiching both N-type and P-type semiconductors together. Whereas typical PN junction diodes are classified as bipolar devices, Schottky diodes are classified as unipolar devices.

The uses of semiconductor diodes in devices constructed for radiation detection and/or power generation are various. For example, a photovoltaic cell employs a semiconductor diode that, when exposed to photons (from incidental electromagnetic radiation such as light), produces uncompensated charge carriers that migrate to electrodes at the surfaces of the diode. In turn, an electrical current flows through the electrodes of the photovoltaic cell.

An alpha and/or beta (PN-junction) voltaic battery functions by deliberately exposing semiconductor material of a PN junction diode to beta or alpha or proton particles emitted from a radioactive material as it decays. These particles enter into the matrix of the semiconductor material and ionize the atoms of the semiconductor material. In turn, uncompensated charge carriers are created along the path of the energetic particles and, in the presence of a static electric field with respect to the PN junction diode, charge flows to result in electric current through the electrodes.

An alpha and/or beta and/or proton (Schottky) voltaic battery functions by deliberately exposing semiconductor material of a Schottky diode to beta or alpha or proton particles emitted from a radioactive material as it decays. These particles enter into the matrix of the semiconductor material and ionize the atoms of the semiconductor material. In turn, uncompensated charge carriers are created along the path of the energetic particles and, in the presence of a static electric field with respect to the Schottky diode structure, charge flows to result in electric current through the electrodes.

The portion of the overall volume of semiconductor material in semiconductor devices such as the diodes described above that can be made functionally sensitive to radiation has been limited by material and electrical parameters that are themselves constrained by the composition and structure of the semiconductor devices themselves. In addition, this “sensitive volume” is bounded by the distances within which recombination of electrons and holes is more probable than their continued propagation towards electrodes. Such distances are a function, at least in part, of the characteristic electric field in the devices, the charge transport speed, and defects in the semiconductor material that can trap charges. Other constraints can limit the sensitive volume of such semiconductor devices.

It has been proposed in United States Patent Application Publication No. 2013/0056712 to Jain to use an externally applied electric field to vary the width of the depletion region in semiconductor material and/or to enhance charge-carrier mobility, and to provide such an electric field using an electret.

An electret is a component formed of a dielectric material having a quasi-permanent electric charge or dipole polarization, which results in internal and external electric fields. An electret may be thought of as the electrostatic equivalent of a permanent magnet. For example, an electret, like a magnet, is a dipole. In addition, in a manner analogous to a magnet producing a magnetic field, an electret produces an electrostatic field. Known electrets can hold fields with charges ranging in potential from volts to kilovolts, without requiring or generating electrical current. Furthermore, an electret's charge can be stable over months to many years depending upon the materials and production methods used to produce the electret. Electrets can be constructed to be reasonably tolerant to heat, making them suitable for use in a number of applications.

Some early work characterizing electrets is set out in the publication Mototarô Eguchi (1925) XX. entitled “On the permanent electret”, The London, Edinburgh, and Dublin Philosophical Magazine and Journal of Science, 49:289, 178-192, DOI:10.1080/14786442508634594.

According to the Jain document, devices are provided that include one or more functional semiconductor elements, with the functional semiconductor elements immersed in static electric fields. In one embodiment, the Jain document describes the placement of one or more electrets proximate to one or more organic, inorganic, or hybrid semiconductor elements so that the static charge(s) of the electret(s) participate in creating the static electric field(s) that influence the semiconductor elements.

United States Patent Application Publication No. 2018/0366650 to Yokoyama et al. discloses mixing a predetermined amount of electret material into an organic semiconductor material to address the technical problem of, without impairing conductivity, providing an organic semiconductor thin film having a reduced refractive index.

The electret components of Jain and Yokoyama et al. are prepared by being exposed to a uniform—or homogenous—external electric field so that the resulting dipole arrangements in the electret components themselves are homogeneous. In turn, these electret components can expose regions of interest containing those semiconductor components to be influenced with only homogeneous electric fields: those varying throughout neither in strength nor in orientation.

It will be appreciated that, while electrets can be made to be stable over months and even years, they do degrade over time. This results in a degradation of the electric field that can be imparted to semiconductor components.

Various contributions to the field of electret applications have been made. For example, U.S. Pat. No. 2,876,368 to Alexander disclosed a nuclear electret battery intended to generate electrical energy in response to nuclear reactions and for releasing the static energy of an electret to generate an electric current.

U.S. Pat. No. 3,949,178 to Hellstrom et al. disclosed using radioactivity to maintain the charge of an electret device. The electret device is formed with a dielectric layer containing electret charges and a radioactive layer on one of the surfaces of the dielectric layer.

U.S. Pat. No. 3,644,605 to Sessler et al. disclosed a method for producing permanent electret charges in dielectric materials. Stable thin film electrets are produced by directing an electron beam on a dielectric material in a controlled fashion. Electron absorption in the film and induced secondary emission, both from the film and from an adjacent dielectric surface, aid in producing stable electrets with superior charge characteristics and very long lifetimes.

United States Patent Application Publication No. 2015/0295101 to Potter disclosed methods for enhancing the decoupling of excitons (bound electron-hole pairs) in an active layer by placing an insulator with a fixed static charge adjacent to the active layer.

United States Patent Application Publication No. 2017/0170674 also to Potter disclosed a method for trapping electrons includes providing an insulator structure comprising at least two insulator layers. Two or more spaced apart electrical contacts to an interface between the at least two insulator layers are formed. An electrical bias is formed for a period of time across the two or more spaced apart electrical contacts in the insulator structure to fill electron traps at the interface between the at least two insulator layers.

U.S. Pat. No. 10,451,751 to Cao et al. disclosed charge generating devices and methods of making and use thereof. The charge generating devices comprise a substrate having a top surface; a plurality of spaced-apart three-dimensional elements disposed on the top surface of the substrate; and a plurality of cavities formed by the plurality of spaced-apart three-dimensional elements, the plurality of cavities being in the area between the plurality of spaced-apart three-dimensional elements. The charge generating devices can further comprise a radioactive layer disposed on at least a portion of the plurality of spaced-apart three-dimensional elements and the top surface such that the plurality of cavities and the top surface are substantially coated by the radioactive layer. In some examples, the charge generating devices can comprise a radiation material and/or a scintillating material disposed within at least a portion of the plurality of cavities.

British Patent No. 266,499 to Graham et al. disclosed methods for producing durable and practical polarized electrostatic devices, or “electrets”.

Chinese Patent Application Publication No. 101882650 to Ding et al. disclosed a method for improving a single crystal silicon solar cell including using a corona injection method to introduce a negative charge layer into a SiO2/SiNx double-layer film.

Chinese Patent Application Publication No. 103681889 to Liu et al. disclosed introducing an electret thin layer into a traditional solar cell structure to improve the monochromatic incident photon-to-electron conversion efficiency of the solar cell.

High-energy charged particles, x rays, and gamma rays from nuclear decay and electronic devices can penetrate 10's of micrometers into a material. Electron-hole pairs are created all along their path of travel through the material. In the case of charged alpha particles, protons (¹H), tritons (³H), atomic nuclei, and muons the greatest proportion of the energy is converted into electron-hole pairs as the particle approaches the end of the particle range in the material. High-energy photons, from radiation sources that produce x-rays and gamma rays also yield multiple electron-hole pairs due to interaction mechanisms called Compton effects and pair production. These electron-hole production mechanisms are the fundamental principle for detection and measuring radiation in diode devices and generating charge in energy harvesting devices, as is related in this patent description.

In contrast, the greatest proportion of photo-electric generated electron-hole pairs are produced from a broad spectrum solar light source (UV, VIS, IR, FIR, and similar) at a depth typically under 10 micrometers, and a given photon tends to yield one electron-hole pair (in rare cases two electrons) at the end of the photon path. This is the typical mechanism for the photovoltaic cell production of electrical current. Furthermore, any excess energy transferred by the photon to the electron production serves to heat the material rather than produce electron-hole pairs.

### SUMMARY OF THE INVENTION

In accordance with an aspect, there is provided a device comprising: at least one functional semiconductor element; and a static electric field source associated with the at least one functional semiconductor element, the static electric field source comprising at least one electret component and having a heterogeneous charge distribution.

In an embodiment, the at least one electret component comprises at least one electret component having a heterogeneous charge distribution.

In an embodiment, the at least one electret component having a heterogeneous charge distribution has a charge distribution pattern.

In an embodiment, the charge distribution pattern comprises at least one charged region and at least one differently charged region. In embodiments, a differently charged region may be an uncharged region, or may be a region having a higher or lower magnitude of charge than the charged region. The charged, lesser charged, and uncharged regions form a uniform charged surface, heterogeneous-patterned charged surface, or a heterogeneous-pattern charged volume.

In an embodiment, each of the at least one charged region has a heterogeneous charge distribution.

In an embodiment, the heterogeneous charge distribution of each of the at least one charged region comprises a greater charge at the interior of the charged region than at the periphery of the charged region.

In an embodiment, each of the at least one charged region is adjacent to a respective one of the functional semiconductor elements.

In an embodiment, the charge distribution pattern comprises at least one negatively charged region and at least one positively charged region.

In an embodiment, each of the at least one positively charged region has a heterogeneous charge distribution.

In an embodiment, the heterogeneous charge distribution of each of the at least one positively charged region comprises a greater positive charge at the interior of the positively charged region than at the periphery of the positively charged region.

In an embodiment, each of the at least one positively charged region is aligned with a respective one of the semiconductor elements in the array.

In an embodiment, each of the at least one negatively charged regions has a heterogeneous charge distribution.

In accordance with another aspect, there is provided a device comprising: a functional semiconductor element; a static electric field source comprising at least one electret element, the static electric field source imparting a static electric field to the functional semiconductor element; and at least one nuclear radiation source for continuously imparting nuclear beta radiation to the at least one electret element and/or the functional semiconductor element.

In an embodiment, a first of the at least one electret element is associated with a positive electrode of the functional semiconductor element.

In an embodiment, the at least one nuclear radiation source is associated with the positive electrode of the functional semiconductor element.

In an embodiment, the at least one nuclear radiation source is associated with a negative electrode of the functional semiconductor element.

In an embodiment, the at least one nuclear radiation source is associated with the positive electrode and a negative electrode of the functional semiconductor element.

In an embodiment, a first of the at least one electret element is associated with a negative electrode of the functional semiconductor element.

In an embodiment, the at least one nuclear radiation source is associated with a positive electrode of the functional semiconductor element.

In an embodiment, the at least one nuclear radiation source is associated with the negative electrode of the functional semiconductor element.

In an embodiment, the at least one nuclear radiation source is associated with a positive electrode and the negative electrode of the functional semiconductor element.

In an embodiment, the static electrical field source comprises at least two electret elements.

In an embodiment, a first of the at least two electret elements is associated with a positive electrode of the functional semiconductor element; and a second of the at least two electret elements is associated with a negative electrode of the functional semiconductor element.

In an embodiment, the at least one nuclear radiation source is associated with the positive electrode of the functional semiconductor element.

In an embodiment, the at least one nuclear radiation source is associated with the negative electrode of the functional semiconductor element.

In an embodiment, the at least one nuclear radiation source is associated with both the positive electrode and the negative electrode of the functional semiconductor element.

In an embodiment, the first and the second of the at least two electret elements impart electric fields of different strengths.

In an embodiment, the first and the second of the at least two electret elements impart electric fields in different directions.

In an embodiment, the functional semiconductor element is selected from the group consisting of: a PN junction diode, a Schottky diode, a photovoltaic diode, a light-emitting diode (LED), a Zener diode, an avalanche diode, a varactor diode, a tunnel diode, and a laser diode.

In an embodiment, the functional semiconductor element and the static electric field source are integrated, and the at least one nuclear radiation source is separable from the functional semiconductor element and the static electric field source.

In an embodiment, the functional semiconductor element, the static electric field source, and the at least one nuclear radiation source are integrated.

In an embodiment, the at least one nuclear radiation source is arranged with respect to the at least one electret to increase the charge of the at least one electret.

In an embodiment, the at least one nuclear radiation source is arranged with respect to the at least one electret to reduce or increase energy of charged particles traversing the semiconductor material.

In an embodiment, the at least one nuclear radiation source further imparts at least one of alpha particles, proton, triton, muon, recoil mass, x-rays, gamma rays, and energetic photons to the at least one electret element and/or the functional semiconductor element.

According to an aspect, there is provided a use of at least a radioactive beta source for replenishing charge in an electret.

According to another aspect, there is provided a use of at least a radioactive beta source for simultaneously replenishing charge in an electret and modifying charge mobility of a semiconductor material.

According to another aspect, there is provided a nuclear battery comprising at least one functional semiconductor element; at least one radiation source imparting nuclear radiation to the at least one functional semiconductor element; and at least one electret imparting a static electric field to the at least one functional semiconductor element.

According to the present disclosure, application of an electric field from an electret to devices dealing with high-energy charged particles and photons produce a significant benefit in the efficient transport of charges to the distant electrodes before they recombine. In particular, application of the electric field services to focus electron migration for efficient collection and reducing loss of charges. Various forms of electrets are exceedingly resistant to performance decline from severe nuclear radiation exposure.

In this disclosure, a material exhibiting a semi-permanent electric charge or dipole polarization is combined with, integrated with, or placed adjacent to the solid-state semiconductor, gel, or liquid based radiation detectors, nuclear batteries, or photo-electric devices to increase the size of the useful charge collection volume and charge collection efficiency from the irradiated volume of the detector or battery or photodiode device. Such a material may be referred to as an electret.

The static, self-replenishing charge of an electret enhances charge separation efficiency of the electron-hole pairs that are generated when ionizing radiation passes into or through the semiconductor devices, and increases the extraction efficiency of those electrons for useful work. Furthermore, the introduction of the electric field in the semiconductor material by the electret will increase the volume for efficient transfer of charge through the material under irradiation by energetic photons and/or particles.

In one embodiment, including a beta emitting radioisotope source is placed near to the electret so to inject electrical charge into the electret to sustain the electret charge field and lifetime. Beta emitting radio isotopes, either those that are pure beta emitting, those that are mixed with radio isotopes that emit other radiation types, and/or those that are mixtures of various radio isotopes that serve to both charge the electret and inject charge in the devices, are described herein.

Commonly, a “permanent” electret is a dielectric sheet with a metal electrode(s) on one or more surfaces. To use the electret with the semiconductor devices, such as diodes, the electret is positioned in close proximity to (or attached to) the devices and is connected to the devices by means of a simple electrical circuit.

While the Jain patent application, for example, mentions the use of x-rays, UV, and infrared as a stimulating photoelectric source, it does not suggest the use of associated nuclear decay radiation (such as decay particles, recoil nuclei, gamma rays) as the stimulating source or as an integral part of the device. Furthermore, the Jain patent application only describes the source of “light” coming from outside of the patented device. In the principle applications, the present application contemplates incorporating the nuclear decay source (the radiation source component) as integral with the semiconductor device and its packaging.

In embodiments, electret components are produced by injecting charge to polarize dielectric material prior to integration with a semiconductor device, and then conducting the integrating. Alternatively, the dielectric material to be polarized is first integrated unpolarised with the semiconductor device and then subjected to a charging electric field thereby to polarize the dielectric material thereby to form the electret. In embodiments, a radiation source continuously thereafter injects charge into the electret from a nuclear beta decay source while the semiconductor device is in service.

The principles disclosed herein are usable for the integration or inclusion electrets in applications involving of nuclear voltaic batteries, and nuclear & radiation detectors to enhance the power and efficiency of long-lived efficient power sources, and for devices for the detection and measurement of radiation interacting with a variety of diode types such as the Schottky diode.

Other aspects and embodiments will become apparent upon reading the following description.

### BRIEF DESCRIPTION OF THE DRAWINGS

Embodiments of the invention will now be described with reference to the appended drawings in which:

FIG. 1 shows a number of side elevation views of electret components;

FIG. 2 shows a side elevation view of different kinds of ionizing radiation interacting with semiconductor material in a diode;

FIG. 3 shows a number of side sectional views of functional semiconductor elements;

FIG. 4 shows a number of side sectional views of PN junction diodes;

FIG. 5 shows a number of side sectional views of solar cells;

FIG. 6 shows a number of side sectional views of Schottky diodes;

FIG. 7 shows a number of side sectional views of 3D Schottky diodes;

FIG. 8 shows a number of side sectional views of 3D Schottky diodes having various different placements of electret components and radiation source components with respect to their electrodes;

FIGS. 9A and 9B show a top view and a sectional side view of an array of Schottky diodes;

FIGS. 10A and 10B show a top view and a sectional side view of an array of Schottky diodes having an electret component with a charge distribution;

FIGS. 11A and 11B show a top view and a sectional side view of an array of Schottky diodes having an electret component with a heterogeneous charge distribution;

FIGS. 12A and 12B show a top view and a sectional side view of an array of Schottky diodes having an electret component with a heterogeneous charge distribution; and

FIGS. 13A and 13B show a top view and a sectional side view of an array of Schottky diodes having an electret component with a heterogeneous charge distribution.

### DETAILED DESCRIPTION

In this description, an electret material is incorporated into the design, construction, and electrical structure of radiation detectors, nuclear batteries, or photoelectric devices. In one embodiment, the electret material is in the form of a film. Such an electret film functions provides a quasi-permanent electric field that increases or expands the effective charge collection region within these devices without the need of a power source. Ionizing radiation or photoelectric induced charges induced in the charge collection region are more efficiently collected at the device electrodes with the presence of the electric field supplied by the electret, providing an unpowered alternative to systems that incorporate actively powered voltage bias. The static, quasi-permanent electric field created by the electret more effectively separates radiation-induced free electrons from the positively charged sites in the device and increases the transport of the electrons to the electrode without the need for an active power source. By enhancing the collection volume region and the charge separation efficiency of electron-hole pairs generated by the radiation passing into and through the devices, the available induced electrical current of the device is increased for storage or work functions.

One benefit of incorporating an electret into the structural design of a device such as a detector, nuclear battery, or photoelectric device is a measurable increase in electrical charge that can be collected by the device electrodes in response to external radiation incident on the device. The improved charge collection efficiency has significant implications for increasing available electric current to power devices, since less radiation is required to product equivalent power. Furthermore, as compared with alternative approaches involving actively powered devices, benefits include reduced weight of the device, and reduced cost of production relative to power produced.

Other benefits to the semi-permanent electric field producing a bias voltage include increasing electron mobility speed, increasing the efficiency of electron collection in response to applied ionizing radiation, and enlarging the volume in the device within which electrons can be efficiently directed to a device electrode.

In this description, devices influenced by the semi-permanent electric field produced by the electret may be any one of a Schottky, PN-junction, photovoltaic or other diode types including but not limited to Zener diodes, varactor diodes, avalanche diodes, tunnel diodes, light emitting diodes (LEDs), and laser diodes.

In embodiments described and depicted herein, the electret is positioned on or in the diode structure to introduce an electrical field into at least the portion of the diode that lies between the diode electrodes. The electret may be adjoined to either or both the positive (+) and the negative (−) electrodes of the diode(s).

Furthermore, the electret may be charged prior to the construction of the device, charged after construction of the device (for example, while in place within the device or in place with respect to the device), and/or recharged after extended use of the device.

In embodiments, the electret may be recharged, increased in charge state or decreased in charge state by placement of a radioactive beta source external to the surfaces of the electret so that the beta particles enter into the electret structure.

Such a beta source may be permanently fixed, exchangeable, or temporarily affixed to the device. Such a beta source may also be combined with radioactive sources that emit other ionizing emissions, such as alpha particles, x rays, gamma rays, and/or energetic photons along with the beta particles.

Other sources of nuclear radiation than beta radiation sources may be used in conjunction with the semiconductor material, alone or in combination with the beta radiation sources. Such other radiation sources would not function to charge an electret but to cause the formation of electron-hole pairs. In some cases, the radiation particle energy will be degraded and allow maximum electron-hole pair creation at optimal location in the depleted region.

In embodiments, a radioactive beta source may be oriented with respect to the electret and the diode (or other semiconductor device) to impart radiation to change the charge state of the electret or to produce free electrons in the semiconductor device, or both simultaneously. Pure beta particle emitting isotopes of use for continuous charging of the electret during device operation include Ar-39, Ar-42, Be-10, Bi-210, Bk-249, C-14, Ca-45, Cd-113, Cd-113m, Cs-135, Cu-66, Er-169, Er-169, H-3, In-115, Kr-85, Kr-85, Ni-63, Ni-66, P-32, P-33, Pb-209, Pd-107, Pm-147, Pr-143, Pr-145, Pu-241, Re-187, Ru-106, S-35, Se-79, Si-32, Sm-151, Sn-121, Sn-123, Sr-89, Sr-90, Tc-99, Te-127, Tm-171, W-188, Y-90, and Y-91 but may include isotopes that emit mixed radiation types such as alpha-beta, alpha-x-ray, alpha-gamma, etc., and include cascading emissions of charged particles as the parent nuclide transmutes to new daughter products.

Various placements and orientations of electrets and, in respective embodiments, radiation sources, are shown in the accompanying figures.

It will be appreciated that the strength of the electrical charge of the electret may be established to aim towards optimizing the character or performance of the device. In embodiments, the negative pole of the electret is positioned proximal to a particular side of a device while the positive pole of the electret is positioned distal from that particular side. In other embodiments, the positive pole of the electret is positioned proximal to a particular side of a device while the negative pole of the electret is positioned distal from that particular side.

In embodiments involving multiple electrets (for example, two electrets or three electrets or more) being integrated with or being otherwise positioned to impart respective electric fields on to a given device, the different electrets may be configured to share the same charge strength or to have different respective charge strengths. Furthermore, the different electrets may be configured to share the same charge orientation, or have different respective charge orientations. These aspects may depend on whether the different electrets are positioned at the same or respective different faces of the device to which the electric field(s) are to be imparted.

In embodiments, the electret is a planar component. In other embodiments, the electret at least partially conforms to the surface topography of the device.

In embodiments, an electret component is configured with a material that has been conditioned to have a heterogeneous dipole strength and/or a heterogeneous orientation. This, in turn, will impart electric fields having different charge strengths and/or different charge orientations into a region of interest containing the semiconductor device or multiple devices. For example, an electret component may contain regions of zero dipole strength (generally, no particular alignment of dipoles being in the majority in a particular three-dimensional region of the electret component) and other regions of non-zero dipole strength (generally, a particular majority alignment of dipoles in a particular other three-dimensional region of the electret component). The same, or a different, electret component may contain regions of dipole charges that are majority aligned with a Z-axis through the electret component and other regions of dipole charges that are majority aligned off of the Z-axis of the electret component. The provision of a heterogeneous structure having different charge strengths and/or different charge orientations enables the electret component to, depending on the application, act on the semiconductor material in a way that directs, or “funnels”, electron-hole pairs in particular desired directions and at particular desired speeds through the semiconductor material. This may depend on at which point in, and path through, the volume of the semiconductor material the radiation is causing the electron-hole pairs to form, rather than necessarily in a single direction and at a single speed.

The particular strength and/or orientation of the electric field from a given region of the electret component may, in embodiments, be employed to slow down or resist the propagation of energy induced by radiation through the semiconductor material. For example, in some embodiments, the electret's field has a strength and/or orientation to counter or “degrade” the energy of the charged particles emitted by the radiation source that entering the semiconductor material of a diode. The energy of such charged particles can thereby be reduced to maximize the energy transfer from the particle to production of electron-hole pairs in the volume of greatest collection efficiency in the diode. For example, an electret can serve as an energy degrader where alpha emitting radioisotopes, such as Am-241, are used, thereby allowing more of the alpha particles to deposit their energy in the energy-producing diode volume.

The heterogeneous strength and/or orientation of the electret component may be patterned to enable the electret component to overlie or otherwise influence a patterned array of semiconductor components, such as an array of diodes.

In embodiment, multiple layers of electrets—a stack of electret films, for example—may be used in conjunction with one or more semiconductor devices.

The electret or electrets may be formed using a body of a single dielectric material having a uniform density, or alternatively a homogeneous or heterogeneous overall composition of multiple dielectric materials.

Radioisotope diode batteries may be stacked together such that they are all influenced by a single electret component.

In embodiments, metal surfaces on the faces of an electret may serve as one or more electrodes to the diode.

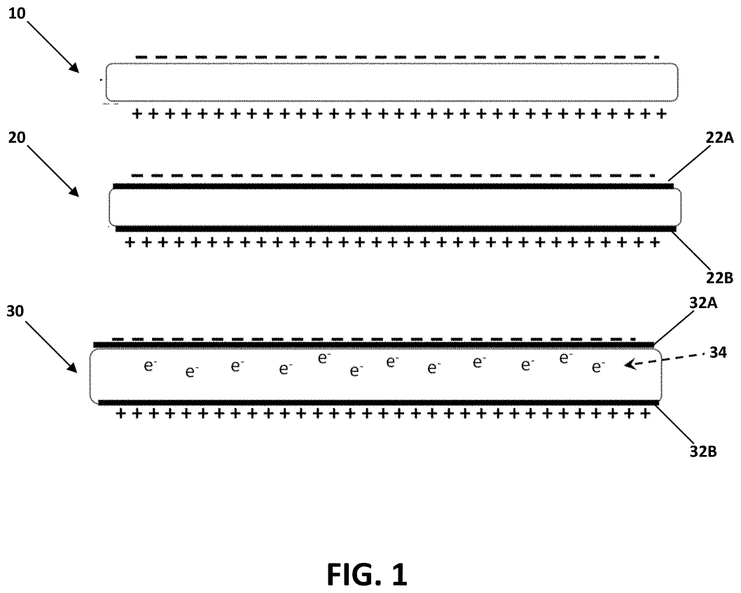

FIG. 1 shows a number of side elevation views of electret components. Shown are an electret component 10 having surface charges, an electret component 20 with metallized top surface 22A and bottom surface 22B having surface charges, and an electret component 30 with metallized top surface 32A and bottom surface 32B having both surface charges and space charges 34.

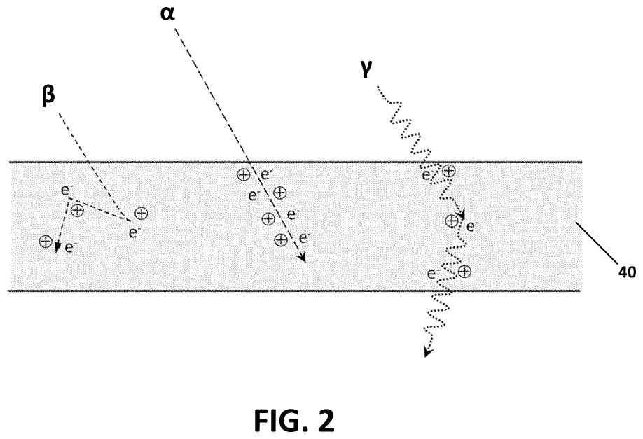

FIG. 2 shows a side elevation view of different kinds of ionizing radiation interacting with semiconductor material 40 in a diode. The ionizing radiation interacting with the semiconductor material creates free electrons and positive charges (known as electron-hole pairs). The number of electrons and positive ions created by the ionizing radiation is variable depending upon the energy of the radiation incident on the material, and the structure of the material being struck by the radiation. Examples of beta (β) radiation, alpha (α) particle or heavier mass radiation and photonic/electromagnetic y radiation are shown.

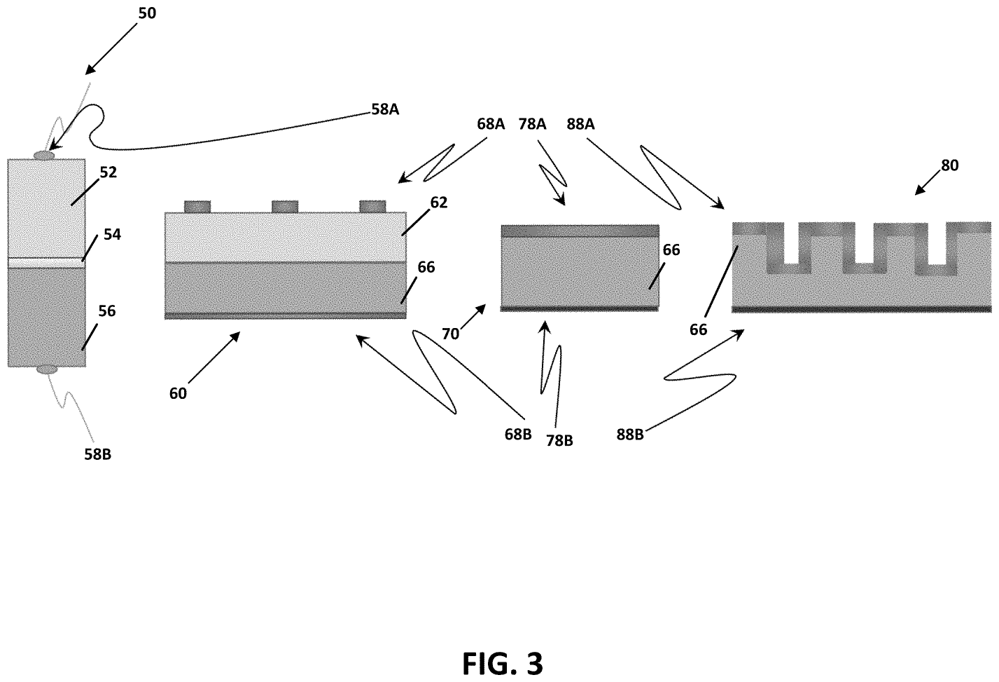

FIG. 3 shows a number of side sectional views of functional semiconductor elements. In this figure, shown is a PN junction diode 50 having P-type silicon 52, N-type silicon 56 and a depletion region 54 therebetween, as well as respective electrodes 58A, 58B. Shown also is a solar cell 60 having a P-type silicon 62, N-type silicon 66, as well as respective electrodes 68A, 68B. Also shown is a Schottky diode 70 having N-type silicon 66 as well as respective electrodes 78A, 78B. A 3D Schottky diode 80 is also shown having N-type silicon 66 and respective electrodes 88A, 88B.

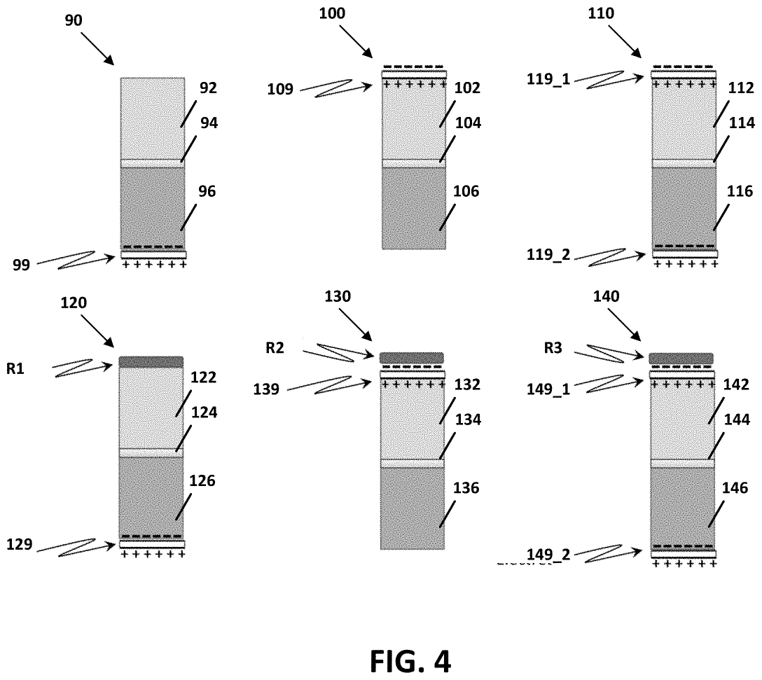

FIG. 4 shows a number of side sectional views of various embodiments of PN-junction diodes 90, 100, 110, 120, 130, and 140. In FIG. 4, the upper row includes PN junction diodes 90 to 110 having respective unique placements of electret components with respect to the locations at which their electrodes (which, for ease of understanding, are not shown) would be affixed.

In particular, diode 90 includes an electret 99 with its negative pole proximal to N-type semiconductor material 96. Diode 90 includes a depletion region 94 and P-type semiconductor material 92.

Diode 100 includes an electret 109 with its positive pole proximal to P-type semiconductor material 102. Diode 100 includes a depletion region 104 and N-type semiconductor material 106.

Diode 110 includes two electrets 119_1 and 119_2. The negative pole of electret 119_2 is proximal to N-type semiconductor material 116 and the positive pole of electret 119_1 is proximal to P-type semiconductor material 112 across depletion region 114 from N-type semiconductor material 116.

Also in FIG. 4, the lower row includes PN junction diodes 120 to 140 having respective unique placements of both electret components and radiation source components with respect to the locations at which their electrodes (which, for ease of understanding, are not shown) would be affixed.

In particular, diode 120 includes an electret 129 with its negative pole proximal to N-type semiconductor material 126. Diode 120 includes a depletion region 124 and P-type semiconductor material 122. Furthermore, a radiation source component R1 is positioned proximal to the P-type semiconductor component 122.

Diode 130 includes an electret 139 with its positive pole proximal to P-type semiconductor material 132. Diode 130 includes a depletion region 134 and N-type semiconductor component 136. Furthermore, a radiation source component R2 is positioned proximal to the negative pole of electret component 139.

Diode 140 includes two electrets 149_1 and 149_2. A negative pole of electret 149_2 is proximal to N-type semiconductor material 146 and a positive pole of electret 149_1 is proximal to P-type semiconductor material 142 across depletion region 144 from N-type semiconductor material 146. Furthermore, a radiation source component R3 is positioned proximal to a negative pole of electret component 149_1.

It will be appreciated that alternative combinations are possible. For example, the radiation source component may be sandwiched between an electret component and the semiconductor material. Furthermore, multiple radiation source components may be provided for a given diode, and may respectively be positioned adjacent to or proximal to the P-type and N-type semiconductor materials. In embodiments, the electret material encapsulates or is otherwise combined with the radiation source component or components.

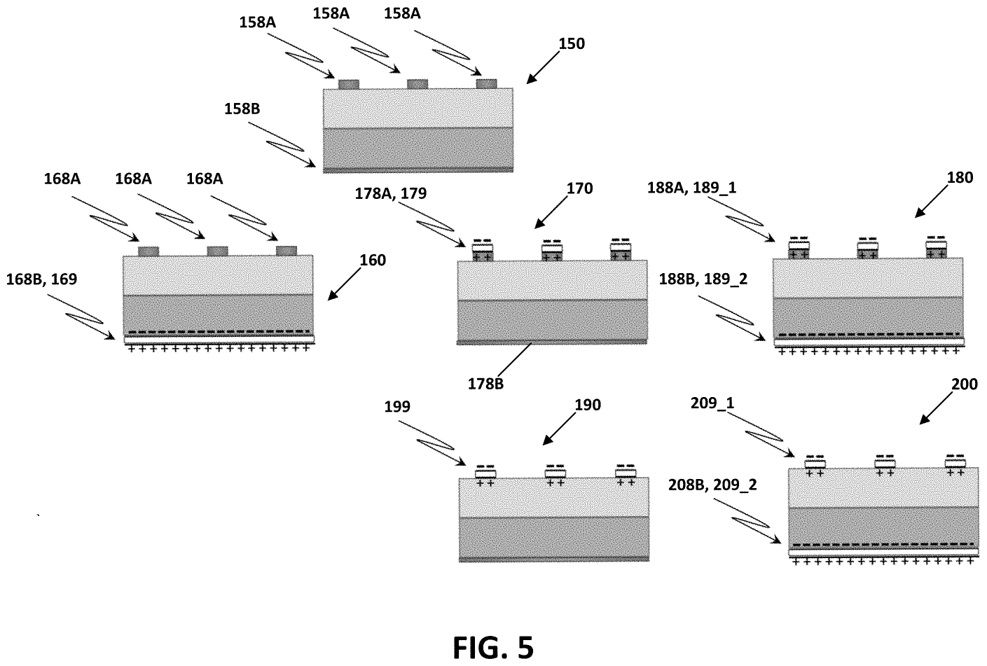

FIG. 5 shows a number of side sectional views of solar cells 150 to 200. Solar cell 150 includes upper electrodes 158A and a lower electrode 158B, without any corresponding electret components.

Solar cell 160 includes upper electrodes 168A and an electret component 169 with its negative pole proximal to N-type semiconductor material and corresponding electrode 168B.

Solar cell 170 includes electret components 179 with their positive poles proximal to P-type semiconductor material and upper electrodes 178A. Solar cell 170 also includes a lower electrode 178B.

Solar cell 180 includes electret components 189_1 with their positive poles proximal to P-type semiconductor material and upper electrodes 188A. Solar cell 180 also includes an electret component 189_2 with its negative pole proximal to N-type semiconductor material and corresponding electrode 188B.

Solar cell 190 includes electret components 199 with their positive poles immediately adjacent to P-type semiconductor material.

Solar cell 200 includes electret components 209_2 with negative poles proximal to N-type semiconductor material and corresponding electrode 208B, and electret components 209_1 with their positive poles immediately adjacent to P-type semiconductor material.

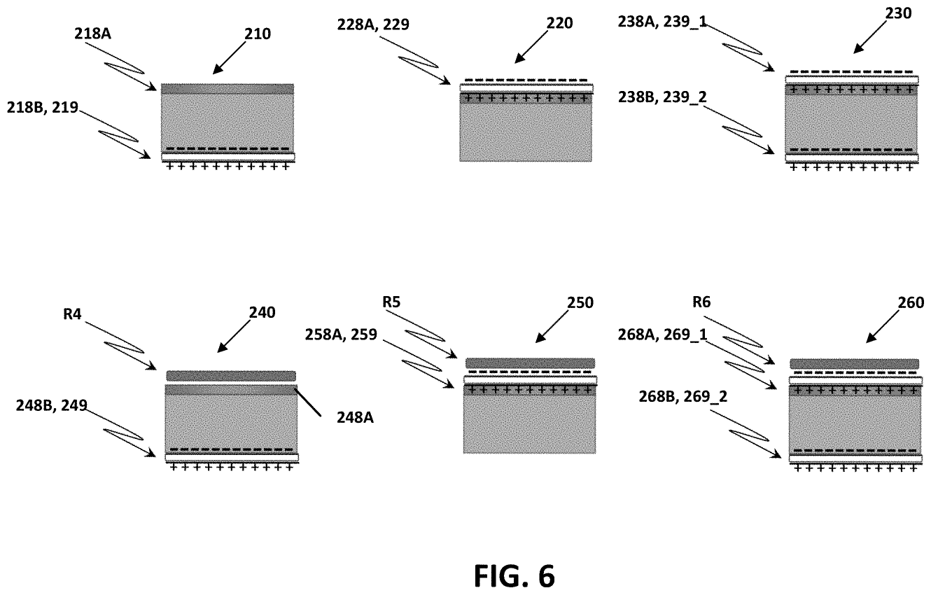

FIG. 6 shows a number of side sectional views of Schottky diodes 210 to 260. Schottky diodes 210 to 230 include respective unique placements of electret components with respect to their electrodes, and Schottky diodes 240 to 260 include respective unique placements of both electret components and radiation source components with respect to their electrodes.

Diode 210 includes an electret component 219 with its negative pole proximal to a lower electrode 218B and opposite diode 210 from electrode 218A.

Diode 220 includes an electret component 229 with its positive pole proximate an upper electrode 228A.

Diode 230 includes an electret component 239_2 with its negative pole proximal to a lower electrode 238B and an electret component 239_1 with its positive pole proximate an upper electrode 238A.

Diode 240 includes an electret component 249 with its negative pole proximal to a lower electrode 248B and a radiation source component R4 proximal to its upper electrode 248A.

Diode 250 includes an electret component 259 with its positive pole proximal to an upper electrode 258A and a radiation source component R5 proximal to a negative pole of electret component 259.

Diode 260 includes an electret component 269_2 with its negative pole proximal to a lower electrode 268B and an electret component 269_1 with its positive pole proximal to an upper electrode 268A, along with a radiation source component R6 proximal to a negative pole of electret component 269_1.

It will be appreciated that alternative combinations are possible. For example, the radiation source component may be sandwiched between an electret component and the semiconductor material. Furthermore, multiple radiation source components may be provided for a given diode, and may respectively be positioned adjacent to or proximal to the semiconductor material. In embodiments, electret material encapsulates or is otherwise combined with the radiation source component or components.

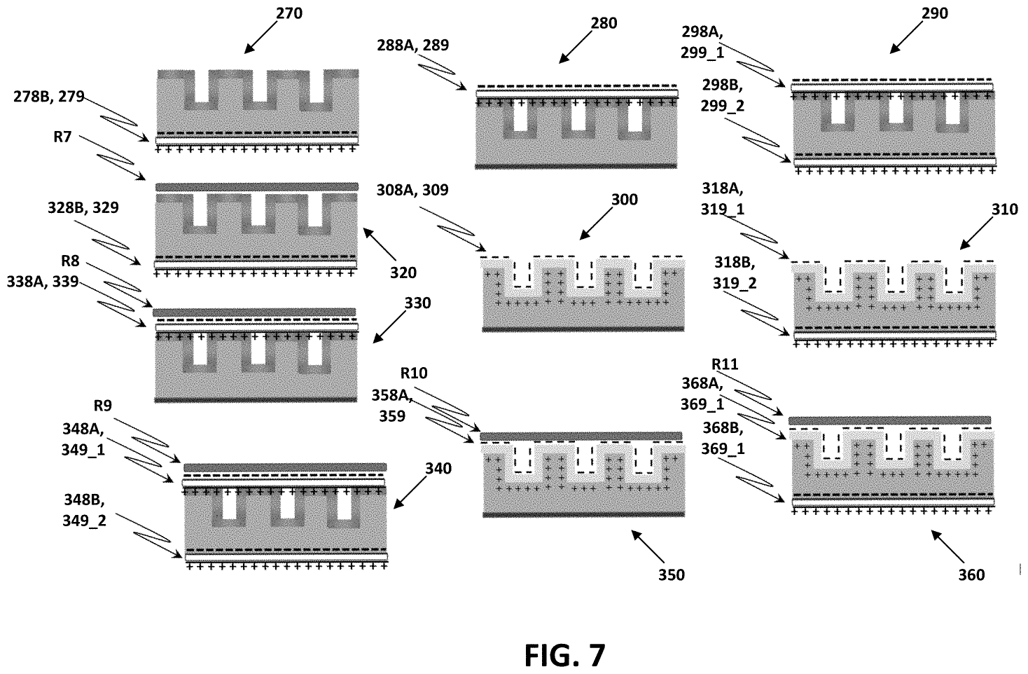

FIG. 7 shows a number of side sectional views of 3D Schottky diodes 270 to 360. In FIG. 7, a portion of a single diode of which there may be many, having perhaps various respective dimensions on a single wafer, is shown. Alternatively, there may be many individual diodes on separate wafers to form a single detector, battery, etc. Such diodes may work together or may function individually for maximum reliability should one fail or to be used individually to produce or read a pattern of radiation that intersects the detector, battery, etc. having various different placements of electret components with respect to their electrodes and, in some examples, various different placements of both electret components and radiation source components with respect to their electrodes.

Diode 270 includes an electret component 279 with its negative pole positioned adjacent to a lower electrode 278B. Diode 280 includes an electret component 289 with its positive pole positioned adjacent to and spanning across contours of an upper electrode 288A. Diode 290 includes an electret component 299_1 with its positive pole positioned adjacent to and spanning across contours of an upper electrode 298A, and an electret component 299_2 with its negative pole positioned adjacent a lower electrode 298B. Diode 300 includes an electret component 309 with its positive pole positioned adjacent to and following contours of an upper electrode 308A. Diode 310 includes an electret component 319_1 with its positive pole positioned adjacent to and following contours of an upper electrode 318A, as well as an electret component 319_2 with its negative pole positioned adjacent to a lower electrode 318B.

Diode 310 includes an electret component 329 with its negative pole positioned adjacent to a lower electrode 328B, and a radiation source component R7 positioned adjacent to and spanning across contours of an upper electrode. Diode 330 includes an electret component 339 with its positive pole positioned adjacent to and spanning across contours of an upper electrode 338A, and a radiation source component R8 positioned adjacent to a negative pole of electret component 339. Diode 340 includes an electret component 349_1 with its positive pole positioned adjacent to and spanning across contours of an upper electrode 348A, and a radiation source component R9 positioned adjacent to a negative pole of electret component 349_1. Diode 340 also includes an electret component 349_2 with its negative pole positioned adjacent to a lower electrode 348B.

Diode 350 includes an electret component 359 with its positive pole positioned adjacent to and following contours of an upper electrode 358A, and a radiation source component R10 positioned adjacent to a negative pole of electret component 359. Diode 360 includes an electret component 369_1 with its positive pole positioned adjacent to and following contours of an upper electrode 368A, and a radiation source component R11 positioned adjacent to a negative pole of electret component 369_1. Diode 360 also includes an electret component 369_2 with its negative pole positioned adjacent to a lower electrode 368B.

As can be seen, in some embodiments an electret component is positioned adjacent to an upper electrode, or adjacent to a lower electrode. In other embodiments, two electret components are positioned, respectively, adjacent to the upper electrode and the lower electrode. In some embodiments, an electret is shaped to conform (at least partially) to the non-planar surface topology of the diode thereby to follow its contour, and other electrets are planar and are either associated with a planar surface topology of the diode or associated with a non-planar surface topology of the diode thereby to span any contour. It will be appreciated that alternative combinations are possible. For example, the radiation source component may, in embodiments, be sandwiched between an electret component and the semiconductor material. Multiple radiation source components may be provided for a given diode, and may respectively be positioned adjacent to or proximal to the semiconductor material. In embodiments, electret material encapsulates or is otherwise combined with the radiation source component or components.

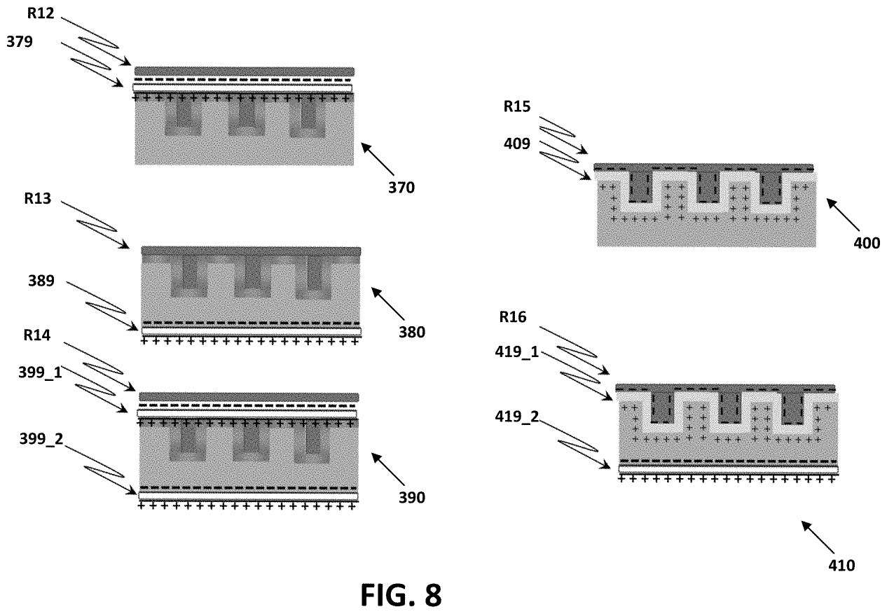

FIG. 8 shows a number of side sectional views of 3D Schottky diodes 370 to 410 having various different placements of electret components and radiation source components with respect to their electrodes. Diode 370 includes an electret component 379 adjacent to an upper electrode and a radiation source component R12 positioned adjacent to a negative pole of electret component 379. Diode 380 includes an electret component 389 adjacent to a lower side and a radiation source component R13 positioned adjacent to and following contours of an upper side of diode 380. Diode 390 includes an electret component 399_1 adjacent to an upper electrode and a radiation source component R14 positioned adjacent to a negative pole of electret component 399_1. Diode 390 also includes an electret component 399_2 positioned adjacent to a lower side. Diode 400 includes an electret component 409 adjacent to and following contours of an upper side of diode 400, and a radiation component adjacent to a negative pole of electret component 409 and following contours of electret component 409. Diode 410 includes an electret component 419_1 adjacent to and following contours of an upper side of die 410, and a radiation component adjacent to a negative pole of electret component 419_1 and following contours of electret component 409. Diode 410 also includes an electret component 419_2 adjacent to a lower side of diode 410.

As can be seen, in some embodiments, the radiation source component is planar, or multiple radiation source components are associated with a 3D Schottky diode and include a planar radiation source component and a non-planar radiation source component. In embodiments, a radiation source has a planar side and a non-planar side thereby to follow contours of an elected component and/or an upper side of the diode. Various alternatives are shown.

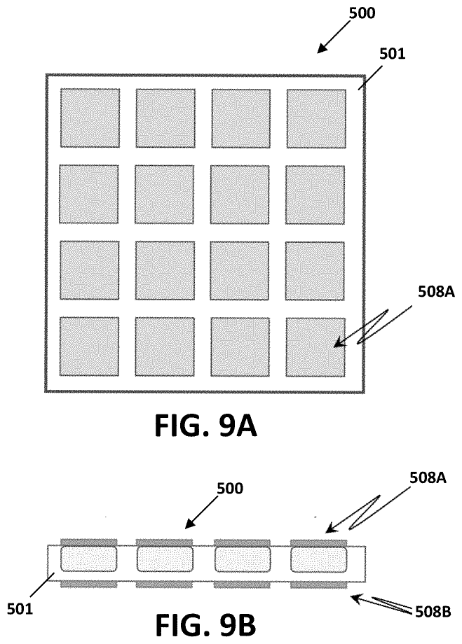

FIGS. 9A and 9B show a top view and a sectional side view of an array 500 of Schottky diodes. In this embodiment, array 500 is a 4×4 array of diodes in a bulk matrix substrate 501. Schottky contacts 508A are shown at an upper side of array 500, whereas Ohmic contacts 508B are shown at a lower side of array 500. While a 4×4 square array of diodes is shown, various arrays may be provides with more or less diodes, in square, rectangular, or irregular dimensions.

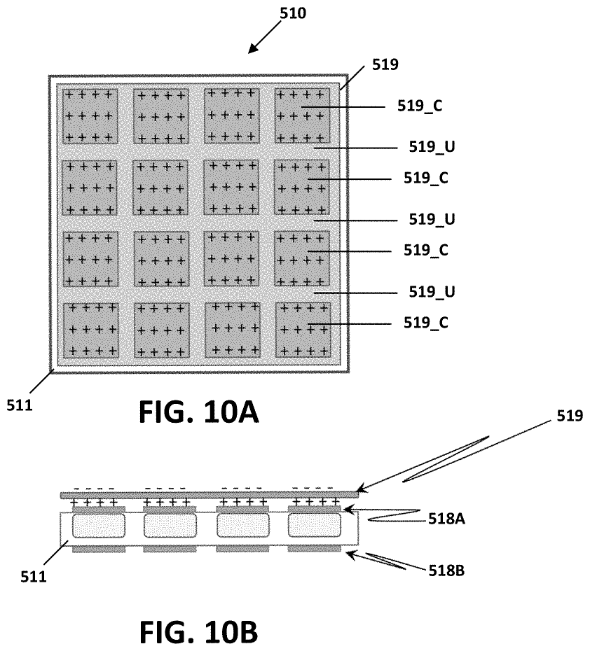

FIGS. 10A and 10B show a top view and a sectional side view of an array 510 of Schottky diodes having an electret component 519 with a heterogeneous charge distribution adjacent to Schottky contacts 518A of components in a bulk matrix 511. In this embodiment the heterogeneous charge distribution is a patterned charge distribution having uncharged regions 519_U and charged regions 519_C. In FIGS. 10A and 10B, only a few uncharged regions 519_U and charged regions 519_C are marked with reference numerals. Each of the charged regions 519_U and 519_C itself has a respective homogeneous charge throughout. Each charged region 519_U, in this embodiment, is adjacent to (in this case, overlies) a respective one of the Schottky diode's Schottky contact 518A. In this embodiment, each uncharged region 519_U separates the charged regions 519_C from each other, thereby creating a grid of spaced charged regions 519_C amidst a matrix of uncharged regions 519_U. By so positioning the uncharged regions 519_U, the charges induced by radiation can more efficiently move from the depletion area of the Schottky diode to the contacts/electrodes. It will be appreciated that, in an alternative embodiment, the electret component having this heterogeneous charge distribution may be positioned adjacent to the Ohmic contacts 518B of the Schottky diodes in the array 510. In an alternative embodiment, the electret component is configured in an opposite manner such that charged regions separate uncharged regions from each other, thereby creating a grid of spaced uncharged regions amidst a matrix of charged regions.

It will be appreciated that, in embodiments, an electret associated with one side of the semiconductor device may be homogeneous in charge while an electret associated with another side of the semiconductor device is heterogeneous in charge. Alternatively, both electrets may be identical in their homogeneity or in their heterogeneity. Alternatively, both electrets may be different in their homogeneity or in their heterogeneity (i.e., in the magnitude, orientation, spacing etc. of their charges).

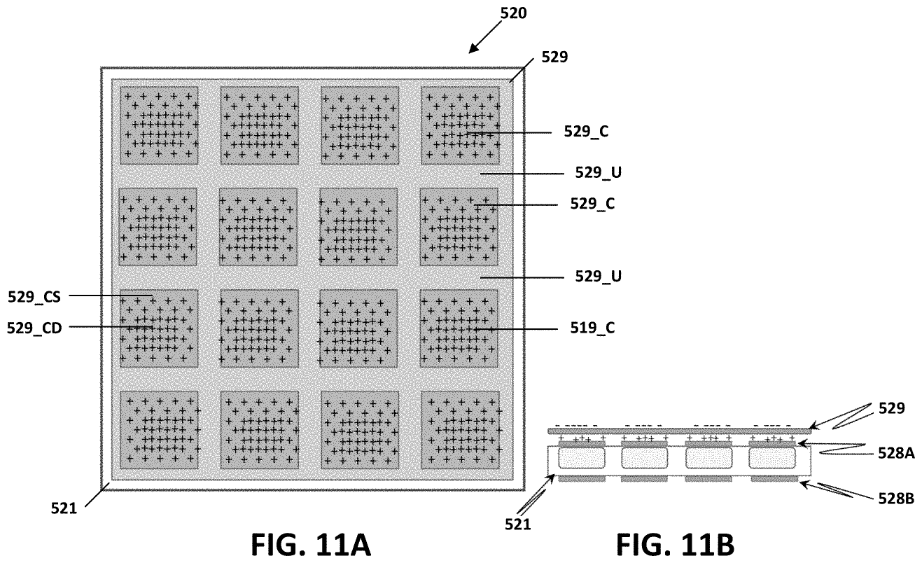

FIGS. 11A and 11B show a top view and a sectional side view of an array 520 of Schottky diodes having an electret component 529 with a heterogeneous charge distribution adjacent to Schottky contacts 528A of components in a bulk matrix 521. In this embodiment the heterogeneous charge distribution is a patterned charge distribution having uncharged regions 529_U and charged regions 529_C. In FIGS. 11A and 11B, only a few uncharged regions 529_U and charged regions 529_C are marked with reference numerals. Each of the charged regions 529_C itself has a respective heterogeneous charge throughout. In particular, the heterogeneous charge distribution of each charged region comprises a greater charge density at the interior of the charged region 529_C than at the periphery of the charged region 529_C, thereby providing a charge gradient. In FIG. 11A, an area within one of the charged regions 529_C having a higher charge density is shown for example as 529_CD whereas an area within the same charged region 529_C having a relatively lower charge density is shown for example as 529_CS. Other charged regions 529_C may have the same charge distribution. Each charged region 529_C, in this embodiment, is adjacent to (in this case, overlies) a respective one of the Schottky diode's Schottky contact 528A. In this embodiment, each uncharged region 529_U separates the charged regions 528_C from each other, thereby creating a grid of spaced charged regions 529_C amidst a matrix of uncharged regions 529_U. By so positioning the uncharged regions 529_U, the charges induced by radiation can more efficiently move from the depletion area of the Schottky diode to the contacts/electrodes. It will be appreciated that, in an alternative embodiment, the electret component having this heterogeneous charge distribution may be positioned adjacent to the Ohmic contacts 528B of the Schottky diodes in the array. In an alternative embodiment, the electret component is configured in an opposite manner such that charged regions separate uncharged regions from each other, thereby creating a grid of spaced uncharged regions amidst a matrix of charged regions.

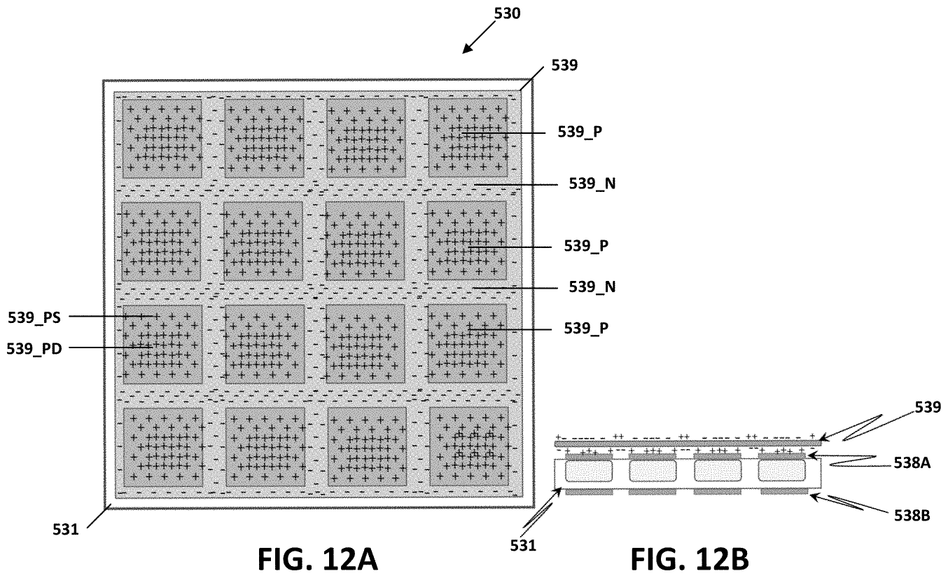

FIGS. 12A and 12B show a top view and a sectional side view of an array 530 of Schottky diodes having an electret component 539 with a heterogeneous charge distribution adjacent to Schottky contacts 538A of components in a bulk matrix 531. In this embodiment, the heterogeneous charge distribution is a patterned charge distribution having negatively charged regions 539_N and positively charged regions 539_P. In FIGS. 12A and 12B, only a few negatively charged regions 539_N and positively charged regions 539_P are marked with reference numerals. Each of the positively charged regions 539_P itself has a respective heterogeneous positive charge throughout. In particular, the heterogeneous charge distribution of each positively charged region 539_P comprises a greater positive charge density at the interior of the positively charged region 539_P than at the periphery of the positively charged region 539_P, thereby providing a charge gradient. In FIG. 12A, an area within one of the positively charged regions 539_P having a higher charge density is shown for example as 539_PD whereas an area within the same positively charged region 539_P having a relatively lower charge density is shown for example as 539_PS. Other positively charged regions 539_P may have the same charge distribution. Each positively charged region 539_P, in this embodiment, is adjacent to (in this case, overlies) a respective one of the Schottky diode's Schottky contact 538A. In this embodiment, each negatively charged region 539_N separates the positively charged regions 539_P from each other, thereby creating a grid of spaced positively charged regions 539_P amidst a matrix of negatively charge regions 539_N. By so positioning the negatively charged regions 539_N, the charges induced by radiation can more efficiently move from the depletion area of the Schottky diode to the contacts/electrodes. It will be appreciated that, in an alternative embodiment, the electret component having this heterogeneous charge distribution may be positioned adjacent to the Ohmic contacts 538B of the Schottky diodes in the array. In an alternative embodiment, the negatively charged regions have a heterogeneous charge distribution. In an alternative embodiment, the electret component is configured in an opposite manner such that positively charged regions separate negatively charged regions from each other, thereby creating a grid of spaced negatively charged regions amidst a matrix of positively charged regions.

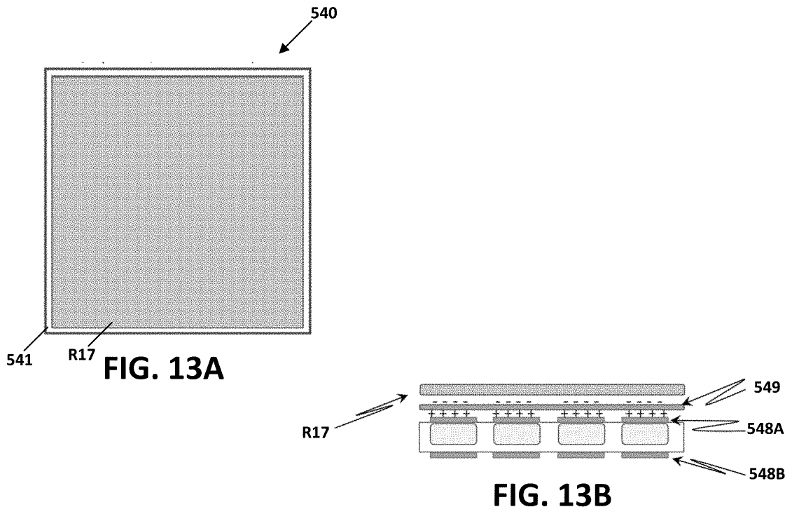

FIG. 13 shows a top view and a sectional side view of an array 540 of Schottky diodes having an electret component 549 with a heterogeneous charge distribution. In this embodiment the heterogeneous charge distribution is a patterned charge distribution having uncharged regions and charged regions. Electret component 549 is positioned adjacent to the Schottky contacts 548A of components in a bulk matrix 541, as well as a radiation source component R17 overlying the electret component 549. It will be appreciated that electret components such as those set out in FIGS. 10 through 12 may be included in this configuration. Furthermore, alternative configurations in which the radiation source component is adjacent to the Ohmic contacts 548B, is between the depicted electret component and the semiconductor material, is opposite the Ohmic contacts from an electret component, or takes other forms, are contemplated.

Although embodiments have been described with reference to the drawings, those of skill in the art will appreciate that variations and modifications may be made without departing from the spirit, scope and purpose of the invention as defined by the appended claims.

For example, while PN-junction, photodiodes, Schottky diodes and solar cells are described and depicted herein as being semiconductor-based devices to which the principles described herein may be applied, the principles described herein are also applicable to other types of semiconductor devices, such as Zener diodes, varactor diodes, avalanche diodes, tunnel diodes, light-emitting diodes (LEDs), and laser diodes.

Also, while electret components having heterogeneous charge distributions therethrough have been described and depicted in association with an array of semiconductor elements, alternatives are possible in which a given electret component having a heterogeneous charge distribution is associated with a single semiconductor element.

Furthermore, while electret components having heterogeneous charge distributions therethrough have been described and depicted, alternatives are possible in which a heterogeneous electric field is imparted to a semiconductor device or an array thereof by positioning multiple discrete electret components (having their own respective uniform or heterogeneous charge distributions) having—collectively—a heterogeneous charge distribution with respect to the semiconductor device.

Furthermore, while embodiments have been described featuring only an electret or electrets as static electric field sources, alternatives are possible in which the static electric field source includes one or more electrets as well as another type of static electric field source.

In addition, while embodiments have been described that employ N-type silicon-based semiconductors, the principles herein may be applied to semiconductors formed of other materials, such as silicon carbide, gallium nitride, and perovskite compounds.

Furthermore, while embodiments described herein depict charged regions in combination with uncharged regions, alternatives are possible in which charged regions having a first magnitude are combined with charged regions having a second magnitude that is different than the first magnitude.

Furthermore, while embodiments have been described and depicted herein that employ one or more electrets of heterogeneous charge along X and/or Y dimensions, embodiments are contemplated in which the heterogeneity is also provided along the Z dimension thereby to provide the possibility of heterogeneity in any, some or all of the dimensions.

Furthermore, embodiments of nuclear batteries having electrets with heterogeneous charge distributions are contemplated along with the other forms of semiconductor devices described more specifically herein (for example, diodes). However, it should be appreciated that the present disclosure contemplates as new the combination of one or more electrets having a homogeneous charge distribution with a nuclear battery. Such a combination can provide advantages to the nuclear battery in the form of improved charge collection, improved control over the energy of the great many electron-hole pairs generated during operation of the nuclear battery (so as to increase or decrease the energy) and control over the directions through the semiconductor that electron-hole pairs traverse. Other semiconductor-based devices that, like nuclear batteries, have semiconductors being exposed to high energy radiation that penetrates deeply into the semiconductor can similarly benefit from associating the semiconductors with appropriately-positioned electret(s) having homogenous and/or heterogeneous charge distributions.

What is claimed is:

1. A device comprising:
at least one functional semiconductor element; and
a static electric field source associated with the at least one functional semiconductor element, the static electric field source comprising at least one electret component and having a heterogeneous charge distribution.

2. The device of claim 1, the at least one electret component comprises at least one electret component having a heterogeneous charge distribution.

3. The device of claim 2, wherein the at least one electret component having a heterogeneous charge distribution has a charge distribution pattern.

4. The device of claim 3, wherein the charge distribution pattern comprises at least one charged region and at least one uncharged or lesser charged region.

5. The device of claim 4, wherein each of the at least one charged region has a heterogeneous charge distribution.

6. The device of claim 5, wherein the heterogeneous charge distribution of each of the at least one charged region comprises a greater charge at the interior of the charged region than at the periphery of the charged region.

7. The device of claim 3, wherein each of the at least one charged region is adjacent to a respective one of the functional semiconductor elements.

8. The device of claim 7, wherein there are a plurality of charged regions.

9. The device of claim 8, wherein the plurality of charged regions have the same charge magnitude.

10. The device of claim 8, wherein the plurality of charged regions include at least one charged region having a different charge strength than at least one other charged region.

11. The device of claim 3, wherein the charge distribution pattern comprises at least one negatively charged region and at least one positively charged region.

12. The device of claim 11, wherein the at least one negatively charged region and at least one positively charged region are located on opposite sides of the device to increase collection of electronics from a depletion region of the device.

13. The device of claim 11, wherein each of the at least one positively charged region has a heterogeneous charge distribution.

14. The device of claim 13, wherein the heterogeneous charge distribution of each of the at least one positively charged region comprises a greater positive charge at the interior (center?) of the positively charged region than at the periphery of the positively charged region.

15. The device of claim 11, wherein each of the at least one positively charged region is aligned with a respective one of the semiconductor elements in the array.

16. The device of claim 11, wherein each of the at least one negatively charged regions has a heterogeneous charge distribution.

17. A device comprising:
a functional semiconductor element;
a static electric field source comprising at least one electret element, the static electric field source imparting a static electric field to the functional semiconductor element; and
at least one nuclear radiation source for continuously imparting nuclear radiation to the at least one electret element and/or the functional semiconductor element.

18. The device of claim 17, wherein a first of the at least one electret element is associated with a positive electrode of the functional semiconductor element.

19. The device of claim 18, wherein the at least one nuclear radiation source is associated with the positive electrode of the functional semiconductor element.

20. The device of claim 18, wherein the at least one nuclear radiation source is associated with a negative electrode of the functional semiconductor element.

21. The device of claim 18, wherein the at least one nuclear radiation source is associated with the positive electrode and a negative electrode of the functional semiconductor element.

22. The device of claim 17, wherein a first of the at least one electret element is associated with a negative electrode of the functional semiconductor element.

23. The device of claim 22, wherein the at least one nuclear radiation source is associated with a positive electrode of the functional semiconductor element.

24. The device of claim 22, wherein the at least one nuclear radiation source is associated with the negative electrode of the functional semiconductor element.

25. The device of claim 22, wherein the at least one nuclear radiation source is associated with a positive electrode and the negative electrode of the functional semiconductor element.

26. The device of claim 17, wherein the static electrical field source comprises at least two electret elements.

27. The device of claim 26, wherein:
a first of the at least two electret elements is associated with a positive electrode of the functional semiconductor element; and
a second of the at least two electret elements is associated with a negative electrode of the functional semiconductor element.

28. The device of claim 27, wherein the at least one nuclear radiation source is associated with the positive electrode of the functional semiconductor element.

29. The device of claim 27, wherein the at least one nuclear radiation source is associated with the negative electrode of the functional semiconductor element.

30. The device of claim 27, wherein the at least one nuclear radiation source is associated with both the positive electrode and the negative electrode of the functional semiconductor element.

31. The device of claim 27, wherein the first and the second of the at least two electret elements impart electric fields of different strengths.

32. The device of claim 27, wherein the first and the second of the at least two electret elements impart electric fields with different orientations.

33. The device of claim 17, wherein the functional semiconductor element is selected from the group consisting of: a PN junction diode, a Schottky diode, a photovoltaic diode, a light-emitting diode (LED), a Zener diode, an avalanche diode, a varactor diode, a tunnel diode, and a laser diode.

34. The device of claim 17, wherein:
the functional semiconductor element and the static electric field source are integrated, and
the at least one nuclear radiation source is separable from the functional semiconductor element and the static electric field source.

35. The device of claim 17, wherein
the functional semiconductor element, the static electric field source, and the at least one nuclear radiation source are integrated.

36. The device of claim 17, wherein the at least one nuclear radiation source is arranged with respect to the at least one electret to reduce or increase energy of charged particles traversing the semiconductor material.

37. The device of claim 17, wherein the at least one nuclear radiation source is arranged with respect to the at least one electret to decrease the charge of the at least one electret.

38. The device of claim 17, wherein the at least one nuclear radiation source further imparts at least one of: alpha particles, proton, triton, muon, recoil mass, x-rays, gamma rays, and energetic photons to the at least one electret element and/or the functional semiconductor element.

39. Use of at least a radioactive source for replenishing charge in an electret.

40. The use of claim 39, wherein the radioactive source is a radioactive beta source.

41. Use of at least a radioactive source for simultaneously replenishing charge in an electret and modifying charge mobility of a semiconductor material.

42. The use of claim 41, wherein the radioactive source is a radioactive beta source.

43. A nuclear battery comprising:
at least one functional semiconductor element;
at least one radiation source imparting nuclear radiation to the at least one functional semiconductor element; and
at least one electret imparting a static electric field to the at least one functional semiconductor element.

44. The nuclear battery of claim 43, wherein the at least one electret imparts a homogenous electric field to the at least one functional semiconductor element.

45. The nuclear battery of claim 43, wherein the at least one electret imparts a heterogeneous electric field to the at least one functional semiconductor element.
